(19) United States
(12) Patent Application Publication
(10) Pub. No.: US 2025/0081345 A1
(43) Pub. Date: Mar. 6, 2025

(54) FLEXIBLE PRINTED CIRCUIT BOARD AND ELECTRONIC DEVICE

(71) Applicant: VIVO MOBILE COMMUNICATION CO., LTD., Dongguan (CN)

(72) Inventor: Kui LI, Dongguan (CN)

(73) Assignee: VIVO MOBILE COMMUNICATION CO., LTD., Dongguan (CN)

(21) Appl. No.: 18/954,437

(22) Filed: Nov. 20, 2024

Related U.S. Application Data
(63) Continuation of application No. PCT/CN2023/094509, filed on May 16, 2023.

(30) Foreign Application Priority Data
May 20, 2022 (CN) 202210553415.6

(51) Int. Cl. H05K 1/11; H05K 1/02

(52) U.S. Cl. CPC H05K 1/118; H05K 1/0215; H05K 1/0242

(57) ABSTRACT

This application discloses a flexible printed circuit board and an electronic device. The flexible printed circuit board includes a body part, a coaxial cable, and a terminal disposed in the body part. The coaxial cable is disposed in the body part, and at least one end of the coaxial cable is electrically connected to outside by using the terminal.

### CROSS-REFERENCE TO RELATED APPLICATIONS

This application is a continuation of International Application No. PCT/CN 2023/094509, filed on May 16, 2023, which claims priority to Chinese Patent Application No. 202210553415.6, filed on May 20, 2022. The entire contents of each of the above-referenced applications are expressly incorporated herein by reference.

### TECHNICAL FIELD

This application pertains to the field of communication technologies, and in particular, to a flexible printed circuit board and an electronic device.

### BACKGROUND

Currently, foldable mobile terminals are classified into two types: vertical folding and horizontal folding. Because folding space of a mobile terminal in a vertical folding manner is limited after the mobile terminal is folded, to achieve better experience, antennas need to be distributed at two ends of a folding structure, and modems are usually disposed only on a main board at one end. In this way, signals of antennas distributed at the other end need to be transmitted by using cables to the modems located on the main board for processing.

In a related technology, the two ends of the folding structure are connected by using a Flexible Printed Circuit (FPC) or a coaxial cable, to transmit antenna signals. However, it is difficult for the FPC to meet a transmission loss requirement of the antenna signal, and consequently, communication performance of the foldable mobile terminal is reduced. However, a large-size connector needs to be used for connecting to a Printed Circuit Board (PCB) to the coaxial cable, which is not applicable to a design trend of thinning the foldable mobile terminal.

### SUMMARY

Embodiments of this application are to provide a flexible printed circuit board and an electronic device.

According to a first aspect, an embodiment of this application provides a flexible circuit board, including a body part, a coaxial cable, and a terminal disposed in the body part, where
the coaxial cable is disposed in the body part, and at least one end of the coaxial cable is electrically connected to the outside by using the terminal.

According to a second aspect, an embodiment of this application provides an electronic device, including the flexible printed circuit board according to the first aspect.

The flexible printed circuit board provided in the embodiments of this application includes a body part, a coaxial cable, and a terminal disposed in the body part. The coaxial cable is disposed in the body part, and at least one end of the coaxial cable is electrically connected to the outside by using the terminal. In this way, the coaxial cable is integrated into the body part of the flexible circuit board, and an end part of the coaxial cable can be electrically connected to an external circuit by using the terminal on the flexible circuit board. In a case that the flexible printed circuit board provided in the embodiments of this application is applied to a foldable mobile terminal, a coaxial cable with a low transmission loss can be used to transmit an antenna signal, thereby reducing a transmission loss of the antenna signal; and in addition, the terminal on the flexible printed circuit board is further multiplexed to connect the coaxial cable and a PCB board, thereby reducing space occupied in a case that a connecting socket of a coaxial cable is disposed, and further reducing a size of the foldable mobile terminal.

### BRIEF DESCRIPTION OF DRAWINGS

FIG. 1a is a schematic diagram of a horizontal cross-section of an FPC signal line in a related technology;

FIG. 1b is a schematic diagram of a longitudinal cross-section of an FPC signal cable in a related technology;

FIG. 2 is a schematic diagram of an assembly structure of a flexible printed circuit board on a foldable mobile terminal according to an embodiment of this application;

FIG. 3 is a schematic diagram of a flexible printed circuit board according to an embodiment of this application;

FIG. 4 is a schematic diagram of a cross-section in a direction A-A in FIG. 3;

FIG. 5 is a schematic diagram of a cross-section in a direction B-B in FIG. 3;

FIG. 6 is a schematic diagram of a structure of a body part of a flexible circuit board;

FIG. 7 is a locally enlarged view of a region C in FIG. 6; and

FIG. 8 is a schematic diagram of signal losses of an FPC signal line in a related technology and a flexible printed circuit board according to an embodiment of this application.

### DETAILED DESCRIPTION

The following describes the technical solutions in the embodiments of this application with reference to the accompanying drawings in the embodiments of this application. Apparently, the described embodiments are some but not all of the embodiments of this application. All other embodiments obtained by a person of ordinary skill in the art based on the embodiments of this application without creative efforts shall fall within the protection scope of this application.

The terms “first”, “second”, and the like in this specification and claims of this application are used to distinguish between similar objects instead of describing a specific order or sequence. It should be understood that terms used in such a way are interchangeable in proper circumstances, so that embodiments of this application can be implemented in an order other than the order illustrated or described herein. Objects classified by “first”, “second”, and the like are usually of a same type, and a quantity of objects is not limited. For example, there may be one or more first objects. In addition, in this specification and the claims, “and/or” indicates at least one of connected objects, and a character “/” generally indicates an “or” relationship between associated objects.

With the rapid development of a 5^{th} Generation (5G) communication system and an Internet of Everything technology, people increasingly use and rely on mobile terminals, and users have a gradually high requirement for a size of a display screen of a mobile terminal. To meet a visual experience requirement of the user in a scenario such as browsing a web page, playing a game, or watching a video, the display screen of the mobile terminal is also increasingly large. However, in pursuit of a large display screen, an overall size of the mobile terminal increases accordingly. This reduces portability and holding comfort of the mobile terminal.

With the breakthrough and development of a flexible screen technology, applying the flexible screen to the foldable terminal becomes a development direction. The flexible screen is characterized by portability, flexibility, thin thickness, low power consumption, and light weight. In the future, the flexible screen will be widely used with the continuous penetration of a personal mobile intelligent terminal, and has a wide application prospect.

In addition, to meet an Internet of Everything requirement in the 5G era, the mobile terminal needs to simultaneously accept and process a large quantity of information. Therefore, to find a portable foldable mobile phone that can be adapted to high-speed information transmission and processing in the 5G era becomes an increasingly important research direction of a mobile terminal factory.

Currently, foldable mobile terminals are classified into two types: vertical folding and horizontal folding. Folding space of a vertical folding mobile terminal is limited after the mobile terminal is folded. To achieve better experience, 5G antennas need to be distributed at an upper end and a lower end of a folding structure. A signal received by the antenna distributed at the lower end needs to be transmitted by using a cable to a modem located on a main board at the upper end for processing. In a related technology, the signal is transmitted by using an FPC or a coaxial cable.

For a solution in which the signal is transmitted by using the FPC, it is difficult for a common FPC and a low-loss FPC (for example, a Modified Polyimide (MPI) FPC) to meet a transmission loss requirement of an antenna signal, and it is difficult for a fluorine-based FPC (for example, a Poly tetra fluoroethylene (PTFE) substrate FPC) to meet a durability requirement of the foldable mobile terminal for bending fatigue life.

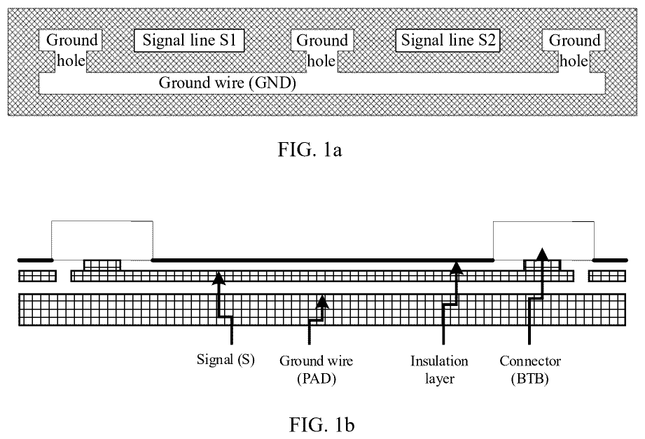

In some embodiments, as shown in FIG. 1a and FIG. 1b, in the common FPC, a radio frequency signal cable generally uses a microstrip line or a strip line. Due to the special feature of a radio frequency signal, a complete return ground cable (GND) needs to be disposed near the radio frequency signal line S1 or S2. However, to enable the FPC to obtain an excellent bending characteristic, a ground hole cannot be arranged in a bent region of the FPC. Consequently, radio frequency signal lines are discontinuous in terms of impedance or are easily interfered with by an external signal, which seriously affects transmission of the radio frequency signal and causes problems such as a large loss and poor signal quality at an output end, and in addition, this structure occupies relatively large space, which is contrary to a development direction of lightening of an intelligent mobile terminal.

For a solution in which the signal is transmitted by using the coaxial cable, although the coaxial cable is superior to the FPC in terms of electrical performance and can meet a bending fatigue life to some extent, large space is occupied by a connector of the coaxial cable, which is contrary to a requirement of the foldable mobile terminal for a device size, and this solution is difficult to be used on a large scale.

In view of this, a flexible printed circuit board is proposed in the embodiments of this application. A coaxial cable is integrated on an FPC, and a ground (GND) of the coaxial cable and a signal line (S) are separately electrically connected to an external circuit by using a terminal designed on the FPC in advance, so that the terminal on the FPC can be multiplexed to transmit a signal transmitted by using the coaxial cable. In this way, a connection component at a tail end of the coaxial cable can be canceled, space occupied by a connector of the coaxial cable can be reduced, and a loss of a high-frequency signal can be reduced by using the coaxial cable when the high-frequency signal is transmitted, thereby improving communication quality of a foldable mobile terminal. In conclusion, the flexible printed circuit board provided in the embodiments of this application can not only meet a requirement of the foldable mobile terminal for a low transmission loss of a signal transmission component, but also reduce occupied space.

With reference to the accompanying drawings, a flexible printed circuit board and an electronic device provided in the embodiments of this application are described in detail below by using specific embodiments and application scenarios thereof.

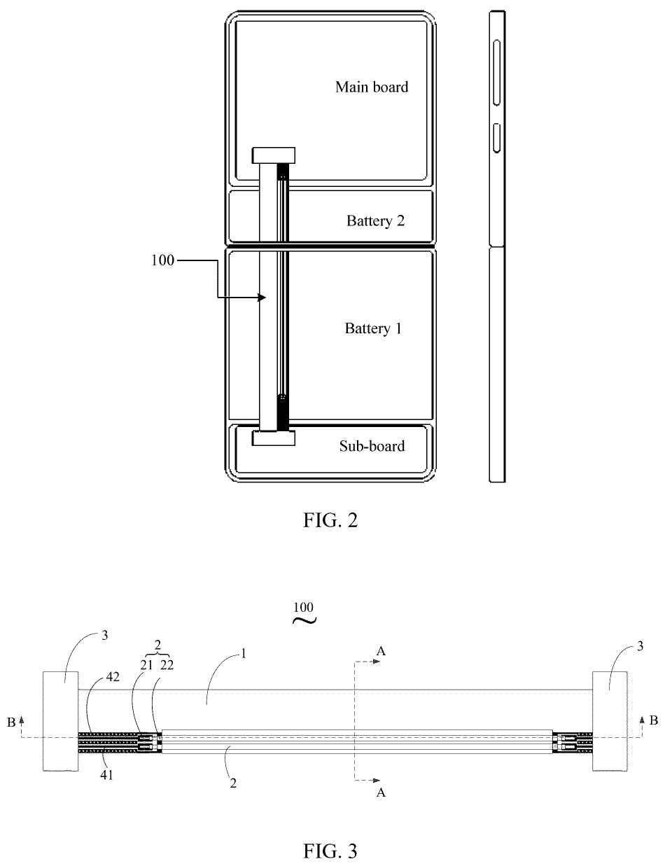

Referring to FIG. 2 and FIG. 3, FIG. 2 is a schematic diagram of an assembly structure of a flexible printed circuit board on a foldable mobile terminal according to an embodiment of this application, and FIG. 3 is a schematic diagram of a flexible printed circuit board according to an embodiment of this application. With reference to FIG. 6, a flexible printed circuit board 100 provided in this embodiment of this application includes a body part 1, a coaxial cable 2, and a terminal 4 disposed in the body part 1.

During implementation, the flexible printed circuit board 100 further includes a board to board (BTB) connector 3. The BTB connector 3 is electrically connected to the terminal 4, and at least one end of the coaxial cable 2 is electrically connected to an external circuit by using the terminal 4 and the BTB connector 3.

In this way, the BTB connector 3 of the flexible printed circuit board 100 may be multiplexed to transmit a signal of the coaxial cable 2, and the coaxial cable 2 is connected to an external circuit by using the BTB connector 3, thereby reducing problems that it is difficult to perform adaptation and it is difficult to implement a miniaturization design because a size of a connector of an existing coaxial cable is excessively large.

In some embodiments, during implementation, the terminal 4 may be connected to an external circuit in another manner. This is not specifically limited herein. For ease of description, in this embodiment of this application, that the terminal 4 is electrically connected to the external circuit by using the BTB connector 3 is used as an example for description, and this is not specifically limited herein.

As shown in FIG. 3, the coaxial cable 2 is disposed in the body part 1, and at least one end of the coaxial cable 2 is electrically connected to the outside by using the terminal 4.

It should be noted that, for ease of description, in this embodiment of this application, that two ends of the coaxial cable 2 are electrically connected to a connector 3 of an FPC respectively by using terminals to be electrically connected to the external circuit by using the connector 3 is used as an example for description. In other words, the flexible printed circuit board 100 includes at least two terminals 4, so that the two ends of the coaxial cable 2 are electrically connected to the outside respectively by using the two terminals 4. During implementation, for example, one end of the coaxial cable 2 may be electrically connected to the outside by using the terminal 4, and the other end may be electrically connected to an external device, circuit, apparatus, or the like in another manner such as welding or by using a coaxial connector. This is not specifically limited herein.

In this embodiment of this application, the coaxial cable 2 is integrated into the body part 1 of the flexible printed circuit board 100, and an end part of the coaxial cable 2 can be electrically connected to the external circuit by using the terminal 4 on the flexible printed circuit board 100. In a case that the flexible printed circuit board 100 provided in this embodiment of this application is applied to a foldable mobile terminal, the coaxial cable 2 with a low transmission loss can be used to transmit an antenna signal, thereby reducing a transmission loss of the antenna signal; and in addition, the terminal 4 on the flexible printed circuit board 100 is further multiplexed to connect the coaxial cable 2 and a PCB board, thereby reducing space occupied because a connecting base of the coaxial cable is disposed in a case that the coaxial cable is directly used to transmit the antenna signal in a related technology, so that a size of the foldable mobile terminal can be reduced.

In an optional implementation, as shown in FIG. 6, the body part 1 is provided with an accommodating part, the accommodating part includes a cavity 10, and the coaxial cable 2 is at least partially disposed in the cavity 10 of the accommodating part.

The accommodating part may be located in the body part 1, so that the coaxial cable 2 is at least partially buried in the body part 1; the end part of the coaxial cable 2 protrudes out of the accommodating part and is exposed outside the body part 1; and the end part of the coaxial cable 2 is electrically connected to the terminal 4.

During implementation, the cavity 10 may be a cavity buried in the body part 1. The coaxial cable 2 is at least partially disposed in the cavity 10 of the accommodating part, so that the coaxial cable 2 can be at least partially buried in the body part 1, to make a structure of the flexible printed circuit board 100 more complete; and the coaxial cable 2 is at least partially buried in the body part 1, so that activity space of the coaxial cable 2 can be limited, to reduce bending fatigue of the coaxial cable 2 in a bending process, thereby enhancing structural strength of the coaxial cable 2.

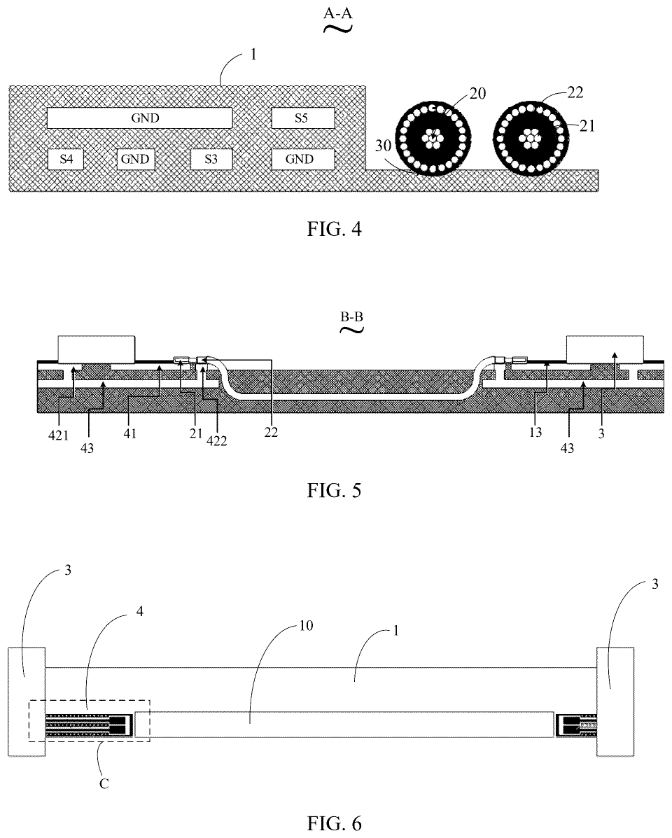

In another optional implementation, as shown in FIG. 4, the coaxial cable 2 is fastened to an outer side of the body part 1, and the accommodating part is disposed on a surface of the body part 1. The accommodating part is located between the two terminals, the accommodating part includes a limiting groove 30, and the coaxial cable 2 is at least partially confined within the limiting groove 30 of the accommodating part.

In this way, the limiting groove 30 is formed on the body part 1, and the coaxial cable 2 is at least partially confined within the limiting groove 30, so that activity space of the coaxial cable 2 can be limited, to reduce bending fatigue of the coaxial cable 2 in a bending process, thereby enhancing structural strength of the coaxial cable 2. During implementation, the coaxial cable 2 may be adhered to a sidewall of the limiting groove 30 in an adhesive manner, so that the coaxial cable 2 is at least partially confined within the limiting groove 30 of the accommodating part, or a width of the limiting groove 30 is slightly less than a width of the coaxial cable 2, so that an outer surface of the coaxial cable 2 and an inner wall of the limiting groove 30 are in interference fit, and in this way, the coaxial cable 2 is at least partially confined within the limiting groove 30 of the accommodating part. This is not specifically limited herein.

In some embodiments, as shown in FIG. 3 and FIG. 4, the coaxial cable 2 includes a conducting wire 21 and a ground wire layer 22 disposed on an outer side of the conducting wire, the conducting wire 21 is coaxial with the ground wire layer 22 and is located in the ground wire layer 22, the conducting wire 21 is insulated from the ground wire layer 22, and the terminal 4 includes a signal terminal 41 and a grounding terminal 42.

The conducting wire 21 is electrically connected to the signal terminal 41.

The ground wire layer 22 is electrically connected to the grounding terminal 42.

The conducting wire 21 may also be referred to as a signal wire. A distribution structure of the conducting wire 21 and the ground wire layer 22 of the coaxial cable 2 in this embodiment of this application is the same as that in a related technology. Details are not described herein again. A difference between this application and the related technology lies in that in this embodiment of this application, the signal terminal 41 and the grounding terminal 42 are disposed in the body part 1 of the flexible printed circuit board 100, so that the conducting wire 21 is electrically connected to the outside by using the signal terminal 41, and therefore, the ground wire layer 22 is electrically connected to the outside by using the grounding terminal 42, while in the related technology, a coaxial cable connector needs to be disposed at an end part of a coaxial cable to electrically connect a signal wire and a ground wire layer of the coaxial cable to the outside.

During implementation, the signal terminal 41 may be electrically connected to the conducting wire 21 through welding, and the grounding terminal 42 may be electrically connected to the ground wire layer 22 through welding. For example, the conducting wire 21 and the ground wire layer 22 may be electrically connected to corresponding terminals in another manner, such as a metal spring or a metal clip. Details are not described herein again.

In an optional implementation, as shown in FIG. 5, the flexible printed circuit board 100 provided in this embodiment of this application further includes a grounding wire 43 buried in the body part 1, and the grounding terminal 42 includes a grounding connection terminal 421 and a coaxial cable grounding terminal 422.

The grounding connection terminal 421 and the coaxial cable grounding terminal 422 are exposed on the body part 1, and the grounding connection terminal 421 and the coaxial cable grounding terminal 422 are electrically connected to the ground wire 43 separately, where the grounding connection terminal 421 is electrically connected to the outside (for example, the BTB connector 3), and the coaxial cable grounding terminal 422 is electrically connected to the ground wire layer 22.

In this implementation, through the grounding wire 43 buried in the body part 1, the grounding connection terminal 421 and the coaxial cable grounding terminal 422 that are disposed at intervals and exposed on the body part 1 are electrically connected.

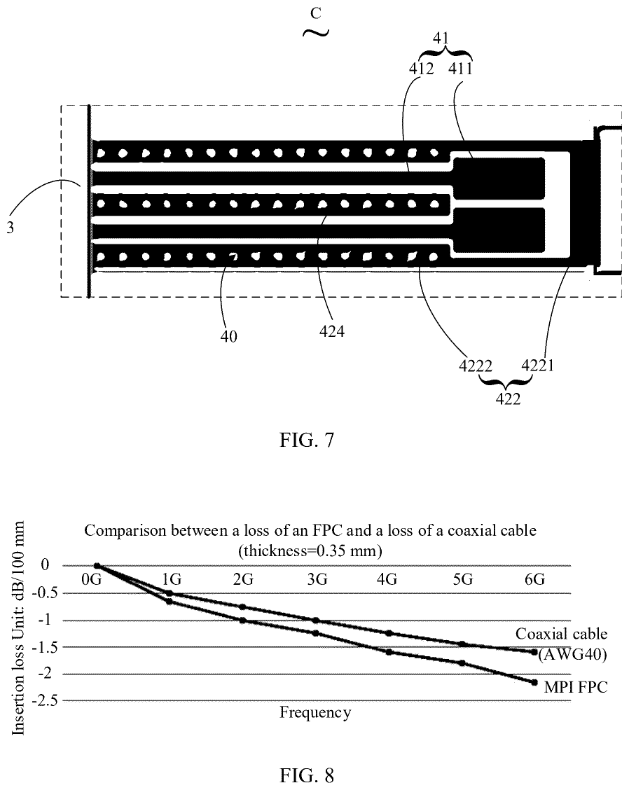

In some embodiments, as shown in FIG. 6 and FIG. 7, with reference to FIG. 5, the grounding terminal 42 includes the coaxial cable grounding terminal 422, the coaxial cable grounding terminal 422 includes a connection part 4221 and a grounding part 4222, the grounding part 4222 is connected to the connection part 4221, and the grounding part 4222 is electrically connected to the grounding wire 43 by using at least one through hole 40 provided in the body part 1, and the connection part 4221 is electrically connected to the ground wire layer 22.

As shown in FIG. 7, during implementation, the ground wire layer 22 may be welded to the connection part 4221 of the coaxial cable grounding terminal 422, and is grounded by using the grounding part 4222 connected to the connection part 4221 and is connected to a grounding port in the BTB connector 3, so that the ground wire layer 22 is connected to the external circuit by using the grounding port.

Similarly, as shown in FIG. 7, the signal terminal 41 may also be divided into a first portion 411 and a second portion 412, where the first portion 411 is electrically connected to the second portion 412, and the conducting wire 21 is configured to be welded to the first portion 411 to be connected to a signal port in the BTB connector 3 by using the second portion 412 electrically connected to the first portion 411, so that the conducting wire 21 is connected to the external circuit by using the signal port.

In addition, in this implementation, a plurality of through holes 40 may be disposed on the body part 1 at intervals along an extension direction of the grounding part 4222, to improve performance of an electrical connection between the grounding part 4222 and the grounding wire buried in the body part 1, thereby improving grounding performance of the terminal 4.

In some embodiments, as shown in FIG. 6 and FIG. 7, the signal terminal 41 includes a first signal terminal and a second signal terminal. The first signal terminal is connected to a conducting wire of one coaxial cable 2. The second signal terminal is connected to a conducting wire of another coaxial cable 2. The grounding terminal 42 includes the coaxial cable grounding terminal 422. The coaxial cable grounding terminal 422 is electrically connected to the grounding wire 43. The coaxial cable grounding terminal 422 has a hollow conductive pattern. Both the first signal terminal and the second signal terminal are located on an inner side of the hollow conductive pattern. An isolated conductive pattern 424 that is electrically connected to the grounding wire 43 is disposed between the first signal terminal and the second signal terminal.

The isolated conductive pattern 424 and the coaxial cable grounding terminal 422 may be electrically connected, in a manner of disposing the through holes 40 on the body part 1, to the grounding wire 43 buried in the body part 1. Details are not described herein again.

In some embodiments, there are two coaxial cables 2. For example, one coaxial cable 2 is used to transmit a TX signal, and the other coaxial cable 2 is used to transmit an RX signal. In a case that the two coaxial cables 2 are disposed in parallel, in this embodiment of this application, signal terminals of the two coaxial cables 2 are disposed inside the hollow conductive pattern formed by the coaxial cable grounding terminal 422, and the isolated conductive pattern 424 is disposed to separate the signal terminals of the two coaxial cables 2. Signal interference between the two coaxial cables 2 can be shielded by using the grounded coaxial cable grounding terminal 422 and the grounded isolated conductive pattern 424.

In some embodiments, as shown in FIG. 5, the flexible printed circuit board 100 provided in this embodiment of this application further includes a first grounding wire (a grounding wire 43 on a left side in FIG. 5) and a second grounding wire (a grounding wire 43 on a right side in FIG. 5) that are buried in the body part 1, and the first grounding wire and the second grounding wire are separated from each other, and the coaxial cable 2 is at least partially located between the first grounding wire and the second grounding wire.

The grounding terminal 42 includes a first coaxial cable grounding terminal (a coaxial cable grounding terminal 422 on the left side in FIG. 5) and a second coaxial cable grounding terminal (a coaxial cable grounding terminal 422 on the right side in FIG. 5), and the first coaxial cable grounding terminal and the second coaxial cable grounding terminal are electrically connected to the ground wire layer 22 on both ends of the coaxial cable 2 respectively.

The first coaxial cable grounding terminal is electrically connected to the first grounding wire, the second coaxial cable grounding terminal is electrically connected to the second grounding wire, and the first grounding wire is connected to the second grounding wire by using the ground wire layer 22 of the coaxial cable 2.

In this implementation, the grounding wire may not be disposed in a region that is on the body part 1 and in which the coaxial cable 2 is located, but the grounding wire is disposed in a region that is on the body part 1 and that is located at an end part of the coaxial cable 2. In this way, in a case that the ground wire layer of the coaxial cable 2 is connected to the coaxial cable grounding terminals 422 on both ends, grounding wires in the body part 1 that are located at both ends of the coaxial cable 2 are connected to each other, so that signal transmission on the coaxial cable can be prevented from being interfered with because the grounding wire is disposed in the region that is on the body part 1 and in which the coaxial cable 2 is located.

In some embodiments, an electrical line on the body part 1 is disposed in a first region on the body part 1, and the first region does not include a region in which the cavity 10 is located.

During implementation, another electrical line such as a control signal line (S3, S4, and S5 in FIG. 3) and a grounding wire may be disposed on the body part 1. In this implementation, these electrical lines are disposed away from the region in which the coaxial cable 2 is located. For example, as shown in FIG. 3 and FIG. 4, no electrical line is disposed in regions of the body part 1 that are located above and under the cavity 10 or the limiting groove 30. In this way, when the coaxial cable 2 is embedded in the cavity 10 or the limiting groove 30, interference caused by other electrical lines in the body part 1 to a signal transmitted by using the coaxial cable 2 can be reduced, thereby improving communication performance of the flexible printed circuit board 100.

In some embodiments, at least one of the conducting wire 21 or the ground wire layer 22 includes N metal wires 20 that are wound through rotation, a diameter of the metal wire 20 is 30 μm to 50 μm, and N is an integer greater than 1.

During implementation, the metal wire 20 may be formed in a pulling-stretching manner, to improve surface smoothness of the metal wire 20. The conducting wire 21 is formed by winding 6 to 7 thin metal wires 20 through rotation, and the ground wire layer 22 is formed by winding a plurality of thin metal wires 20 through rotation. In this way, a complete return ground (that is, the ground wire layer 22) may be surrounded around the conducting wire 21 (that is, the radio frequency signal lines S1 and S2), and the conducting wire 21 and the ground wire layer 22 are formed in a pulling-stretching manner. A surface is smooth, and a material with high conductivity and low magnetic permeability is plated on the surface. In this way, a loss of a signal in a process of being transmitted by using the coaxial cable 2 can be reduced.

As shown in FIG. 4, the insulation layer 23 between the conducting wire 21 and the ground wire layer 22 may be a fluorine-based material layer with a dielectric constant lower than a preset dielectric constant and/or a dielectric loss lower than a preset dielectric loss. In this way, an anti-interference capability of the signal transmitted by using the coaxial cable 2 can be improved.

For example, it is assumed that the conducting wire 21 (including the radio frequency signal lines S1 and S2) is formed by winding 6 to 7 metal wires through rotation, and each metal wire may be a thin wire with a diameter of 30 μm to 50 μm that is formed in a pulling-stretching manner. The ground wire layer 22 is also formed by winding a plurality of thin wires with a diameter of 30 μm to 50 μm through rotation. A first insulation layer is disposed between the conducting wire 21 and the ground wire layer 22, and the ground wire layer 22 is wrapped with a second insulation layer. A layer of material with high conductivity and low magnetic permeability such as silver is separately plated onto surfaces of both the conducting wire 21 and the ground wire layer 22. The first insulation layer is formed by using a fluorine-based material with a low dielectric constant and a low dielectric loss. In this way, a loss of a signal in a process of being transmitted in the conducting wire 21 can be reduced, and an anti-interference capability of the signal is strong, which can well meet a transmission requirement of a radio frequency signal. As shown in FIG. 8, compared with an MPI FPC manner in a related technology, a loss of a signal transmitted by using the coaxial cable 2 in this embodiment is significantly reduced.

In addition, in some embodiments, during implementation, a crystal size and a crystal orientation of the metal wire 20 may be adjusted. With reference to a relatively thin diameter of the coaxial cable 2, the coaxial cable 2 has good winding performance, and meets a requirement of a foldable mobile terminal for constantly bending a folding position.

It should be noted that a surface of the body part 1 may be covered by an insulation layer 13, and at least a portion of the terminal 4 may be exposed on the insulation layer 13, so that the terminal 4 can be electrically connected to the conducting wire 21 and the ground wire layer 22 separately.

As shown in FIG. 2, the flexible printed circuit board 100 provided in this embodiment of this application may be applied to a foldable mobile terminal. The foldable mobile terminal includes a first portion 201 and a second portion 202. A rotating shaft 203 is disposed between the first portion 201 and the second portion 202. The first portion 201 and the second portion 202 may rotate around the rotating shaft 203 to switch between an unfolded state and a folded state. The first portion 201 includes a first PCB board 2011, the second portion 202 includes a second PCB board 2021, and the first PCB board 2011 and the second PCB board 2021 are electrically connected by using the flexible printed circuit board 100.

It should be noted that, in addition to being applied to the foldable mobile terminal, the flexible printed circuit board 100 provided in this embodiment of this application may be applied between any two other circuit boards that are detachably connected or movably connected. This is not specifically limited herein. During implementation, a connecting socket that matches the BTB connector 3 is disposed on the circuit board, so that the BTB connector 3 in the flexible printed circuit board 100 provided in this embodiment of this application can match and be connected to the connecting socket on the circuit board. The BTB connector 3 in the flexible printed circuit board 100 is disposed at opposite ends of the body part 1. Compared with other types of connectors, the BTB connector not only has the strongest transmission capability, but is also characterized by lightness, stable high-frequency transmission, no need for welding, and noise reduction.

An embodiment of this application further provides an electronic device, including the flexible printed circuit board 100 provided in the embodiment shown in FIG. 2 to FIG. 8.

The electronic device provided in this embodiment of this application uses the flexible printed circuit board 100 provided in the embodiments of this application, to meet a requirement of a folding screen mobile terminal for a low transmission loss and a high fatigue life of a signal transmission component. In addition, the flexible printed circuit board 100 provided in the embodiments of this application occupies small space, so that a structure requirement on a component in a lightening direction of a whole machine is met, and user experience is improved.

In some embodiments, the electronic device includes a first portion and a second portion, a rotating shaft is disposed between the first portion and the second portion, and the first portion and/or the second portion rotate around the rotating shaft, so that the electronic device switches between an unfolded state and a folded state. The first portion and the second portion are electrically connected by using the flexible printed circuit board 100.

During implementation, the first portion may include a first PCB board, the second portion may include a second PCB board, and the first PCB board and the second PCB board are electrically connected by using the flexible printed circuit board 100 provided in the embodiment shown in FIG. 2 to FIG. 8.

In this implementation, the electronic device may be a mobile terminal electronic product such as a flexible screen mobile phone, a tablet computer, or an electronic book that use a folding structure. Through use of the flexible printed circuit board 100 provided in the embodiments of this application, a requirement of a folding screen mobile terminal for a low transmission loss and a high fatigue life of a signal transmission component can be met.

In some embodiments, the coaxial cable 2 is configured to transmit an antenna signal between the first portion and the second portion.

During implementation, antennas on the electronic device may be distributed in the first portion and the second portion. However, a processor is generally disposed on the first PCB board in the first portion. In this way, an antenna signal of an antenna disposed on the second portion may be transmitted by using the coaxial cable 2 on the flexible printed circuit board 100. In this way, while bending performance between the first portion and the second portion is met, the flexible printed circuit board 100 can further reduce transmission interference on the antenna signal by using the coaxial cable 2, thereby improving communication performance of the electronic device.

In some embodiments, the body part 1 includes a first region and a second region, both a conducting circuit and the terminal 4 on the body part 1 are located in the first region, the coaxial cable 2 is disposed in the second region, and the end part of the coaxial cable 2 extends to the first region to electrically connect the terminal 4.

In this implementation, the conducting circuit and the terminal 4 on the body part 1 are disposed away from the second region in which the coaxial cable 2 is located, so that interference to the coaxial cable 2 caused by an electrical signal on the conducting circuit and the terminal 4 on the body part 1 can be reduced, and anti-interference performance of the coaxial cable 2 can be improved.

In some embodiments, as shown in FIG. 6, the body part 1 is disposed with an accommodating part (a position that is on the body part 1 and on which the cavity 10 is formed), the coaxial cable 2 is at least partially disposed in the accommodating part, and the accommodating part is located in the second region.

In this implementation, the coaxial cable 2 is at least partially disposed in the accommodating part, and another electrical line or terminal is not disposed in the accommodating part, so that the coaxial cable 2 keeps in the accommodating part in a bending and moving process of the electronic device, and the coaxial cable 2 is prevented from moving to a region with another electrical line or terminal in the bending and moving process of the electronic device, thereby improving anti-interference and stability of the coaxial cable 2.

In some embodiments, the coaxial cable 2 of the flexible printed circuit board 100 includes a conducting wire 21, a ground wire layer 22, and an insulation layer sandwiched between the conducting wire 21 and the ground wire layer 22.

The insulation layer is a fluorine-based material layer with a dielectric constant lower than a preset dielectric constant and/or a dielectric loss lower than a preset dielectric loss; and/or
in a case that at least one of the conducting wire 21 and the ground wire layer 22 is formed by N metal wires 20 that are wound through rotation, a surface of the metal wire 20 is plated with a material layer of high conductivity and low magnetic permeability.

In this implementation, a fluorine-based material layer with a dielectric constant lower than a preset dielectric constant and/or a dielectric loss lower than a preset dielectric loss is disposed between the conducting wire 21 and the ground wire layer 22, so that an anti-interference capability of a signal transmitted by using the coaxial cable 2 can be improved; and/or by plating a material layer with high conductivity and low magnetic permeability on a surface of the metal wire 20, a loss of a signal in a process of being transmitted by using the coaxial cable 2 can be reduced.

In some embodiments, the terminal 4 includes a signal terminal 41 and a grounding terminal 42, and the grounding terminal 42 surrounds a periphery of the signal terminal 41.

In this implementation, the grounding terminal 42 is surrounded on an outer side of the signal terminal 41, and interference caused by an interference signal such as ambient noise to a signal transmitted by the signal terminal 41 can be reduced by using a ground signal loaded on the grounding terminal 42, thereby improving signal transmission performance of the flexible printed circuit board 100.

It should be noted that, in this specification, the term “include”, “comprise”, or any other variant thereof is intended to cover a non-exclusive inclusion, so that a process, a method, an article, or an apparatus that includes a series of elements not only includes those elements but also includes other elements that are not expressly listed, or further includes elements inherent to this process, method, article, or apparatus. In absence of more constraints, an element preceded by “including a . . . ” does not preclude the existence of other identical elements in the process, method, article, or apparatus including the element.

The embodiments of this application are described above with reference to the accompanying drawings, but this application is not limited to the foregoing specific implementations, and the foregoing specific implementations are only illustrative and not restrictive. Under the enlightenment of this application, a person of ordinary skill in the art can make many forms without departing from the purpose of this application and the protection scope of the claims, all of which fall within the protection of this application.

1. A flexible printed circuit board, comprising:
a body part;
a coaxial cable; and
a terminal disposed in the body part,
wherein the coaxial cable is disposed in the body part, and at least one end of the coaxial cable is electrically connected to outside of the body part via the terminal.

2. The flexible printed circuit board according to claim 1, wherein the body part is provided with an accommodating part, the accommodating part comprises a cavity, and the coaxial cable is at least partially disposed in the accommodating part.

3. The flexible printed circuit board according to claim 1, wherein the flexible printed circuit board further comprises a board to board (BTB) connector, the BTB connector is electrically connected to the terminal, and at least one end of the coaxial cable is electrically connected to the outside by using the terminal and the BTB connector.

4. The flexible printed circuit board according to claim 1, comprising two terminals, wherein
two ends of the coaxial cable are electrically connected to the outside via the two terminals, respectively.

5. The flexible printed circuit board according to claim 4, wherein the coaxial cable is fastened on an outer side of the body part, an accommodating part is disposed on a surface of the body part, the accommodating part is located between the two terminals, the accommodating part comprises a limiting groove, and the coaxial cable is at least partially confined within the accommodating part.

6. The flexible printed circuit board according to claim 2, wherein the accommodating part is located in the body part such that the coaxial cable is at least partially buried in the body part, an end part of the coaxial cable protrudes out of the accommodating part and is exposed outside the body part, and the end part of the coaxial cable is electrically connected to the terminal.

7. The flexible printed circuit board according to claim 1, wherein the coaxial cable comprises a conducting wire and a ground wire layer disposed on an outer side of the conducting wire, the conducting wire is insulated from the ground wire layer, and the terminal comprises a signal terminal and a grounding terminal;
the conducting wire is electrically connected to the signal terminal; and
the ground wire layer is electrically connected to the grounding terminal.

8. The flexible printed circuit board according to claim 7, further comprising a grounding wire buried in the body part, wherein the grounding terminal comprises a grounding connection terminal and a coaxial cable grounding terminal; and
the grounding connection terminal and the coaxial cable grounding terminal are exposed on the body part, and the grounding connection terminal and the coaxial cable grounding terminal are electrically connected to the grounding wire respectively, wherein the grounding connection terminal is configured to be electrically connected to the outside, and the coaxial cable grounding terminal is electrically connected to the ground wire layer.

9. The flexible printed circuit board according to claim 7, further comprising a grounding wire buried in the body part, wherein the grounding terminal comprises a coaxial cable grounding terminal, the coaxial cable grounding terminal comprises a connection part and a grounding part, the grounding part is connected to the connection part, the grounding part is electrically connected to the grounding wire by using at least one through hole provided in the body part, and the connection part is electrically connected to the ground wire layer.

10. The flexible printed circuit board according to claim 7, further comprising a grounding wire buried in the body part, wherein the signal terminal comprises a first signal terminal and a second signal terminal, the first signal terminal is connected to a conducting wire of a coaxial cable, the second signal terminal is connected to a conducting wire of another coaxial cable, the grounding terminal comprises a coaxial cable grounding terminal, the coaxial cable grounding terminal is electrically connected to the grounding wire, the coaxial cable grounding terminal has a hollow conductive pattern, both the first signal terminal and the second signal terminal are located on an inner side of the hollow conductive pattern, and an isolated conductive pattern electrically connected to the grounding wire is disposed between the first signal terminal and the second signal terminal.

11. The flexible printed circuit board according to claim 7, further comprising a first grounding wire and a second grounding wire that are buried in the body part, wherein the first grounding wire and the second grounding wire are separated from each other, and the coaxial cable is at least partially located between the first grounding wire and the second grounding wire;
the grounding terminal comprises a first coaxial cable grounding terminal and a second coaxial cable grounding terminal, and the first coaxial cable grounding terminal and the second coaxial cable grounding terminal are electrically connected to ground wire layers at two ends of the coaxial cable respectively; and
the first coaxial cable grounding terminal is electrically connected to the first grounding wire, the second coaxial cable grounding terminal is electrically connected to the second grounding wire, and the first grounding wire is electrically connected to the second grounding wire by using the ground wire layer of the coaxial cable.

12. An electronic device, comprising the flexible printed circuit board according to claim 1.

13. The electronic device according to claim 12, wherein the electronic device comprises a first portion and a second portion, a rotating shaft is disposed between the first portion and the second portion, the first portion or the second portion rotates around the rotating shaft such that the electronic device switches between an unfolded state and a folded state, and the first portion and the second portion are electrically connected by using the flexible circuit board.

14. The electronic device according to claim 13, wherein the coaxial cable is configured to transmit an antenna signal between the first portion and the second portion.

15. The electronic device according to claim 12, wherein the body part comprises a first region and a second region, both a conducting circuit and the terminal in the body part are located in the first region, the coaxial cable is disposed in the second region, and an end part of the coaxial cable extends to the first region to electrically connect to the terminal.

16. The electronic device according to claim 15, wherein the body part is provided with an accommodating part, the coaxial cable is at least partially disposed in the accommodating part, and the accommodating part is located in the second region.

17. The electronic device according to claim 12, wherein the coaxial cable of the flexible printed circuit board comprises a conducting wire, a ground wire layer, and an insulation layer sandwiched between the conducting wire and the ground wire layer;
the insulation layer is a fluorine-based material layer with a dielectric constant lower than a preset dielectric constant or a dielectric loss lower than a preset dielectric loss; and
when at least one of the conducting wire or the ground wire layer is formed by N metal wires that are wound through rotation, a surface of the metal wire is plated with a material layer with high conductivity and low magnetic permeability.

18. The electronic device according to claim 12, wherein the terminal comprises a signal terminal and a grounding terminal, and the grounding terminal surrounds a periphery of the signal terminal.
